(19) United States
(12) Patent Application Publication
(10) Pub. No.: US 2020/0245485 A1
(43) Pub. Date: Jul. 30, 2020

(54) WINDOW ASSEMBLY AND DISPLAY DEVICE INCLUDING THE SAME

(71) Applicant: Samsung Display Co., Ltd., Yongin-si (KR)

(72) Inventor: MYOUNGAN MIN, Cheonan-si (KR)

(21) Appl. No.: 16/704,348

(22) Filed: Dec. 5, 2019

(30) Foreign Application Priority Data
Jan. 29, 2019 (KR) 10-2019-0011294

(51) Int. Cl. H05K 5/03; H05K 5/00; H05K 5/02; H04M 1/02

(52) U.S. Cl. CPC H05K 5/03; H05K 5/0017; H04M 1/0266; H05K 5/0217; H05K 5/0086

(57) ABSTRACT

A display device may include a cover window including a front surface and a rear surface opposite each other, the front surface including a transmission region and a bezel region adjacent to the transmission region, an opening overlapping with the bezel region being defined in the cover window, a stiffener including a supporting portion, which includes a top portion facing the rear surface and is arranged to have a separation gap between the rear surface and the top portion, and an insertion portion, which is bent from the supporting portion and is inserted into the opening, a receiver hole being defined in the insertion portion, and a display panel including a pixel to provide an image to the transmission region. At least a portion of a corner of the supporting portion adjacent to the top portion may have a chamfered shape.

### CROSS-REFERENCE TO RELATED APPLICATIONS

This application claims priority to and the benefit of Korean Patent Application No. 10-2019-0011294, filed on Jan. 29, 2019 in the Korean Intellectual Property Office, the entire content of which is hereby incorporated by reference.

### BACKGROUND

### 1. Field

Aspects of embodiments of the present disclosure relate to a window assembly and a display device including the same.

### 2. Description of Related Art

A mobile apparatus, such as a cellular phone, includes a display panel, which includes pixels and displays an image, and a cover window for protecting the display panel. The display panel may include a liquid crystal display panel or an organic light emitting display panel. An image displayed on the display panel is provided to a user through the cover window.

The cover window may include any of various functional layers (e.g., for improving durability and/or providing an anti-fingerprint function), which may be formed by a printing process.

### SUMMARY

According to an aspect of embodiments of the present disclosure, a window assembly having improved reliability, and a display device including the same, are provided. According to another aspect of embodiments of the present disclosure, a window assembly, which minimizes or reduces interference between an element disposed on a bottom of a cover window and a region printed on the cover window, and a display device including the same, are provided.

According to one or more embodiments of the inventive concept, a display device may include a cover window including a front surface and a rear surface opposite each other, the front surface including a transmission region and a bezel region adjacent to the transmission region, an opening overlapping with the bezel region and being defined in the cover window, a stiffener including a supporting portion, which includes a top portion facing the rear surface and being arranged to have a separation gap between the rear surface and the top portion, and an insertion portion, which is bent from the supporting portion and is inserted into the opening, a receiver hole being defined in the insertion portion, and a display panel including a pixel to provide an image to the transmission region. At least a portion of a corner of the supporting portion adjacent to the top portion may have a chamfered shape.

In an embodiment, the supporting portion may include a bottom portion opposite the top portion and a side portion connecting the top portion to the bottom portion. At least a portion of the side portion may be inclined toward the top portion.

In an embodiment, the portion of the side portion inclined toward the top portion may include a curved portion.

In an embodiment, the supporting portion may include a base portion, which is connected to the insertion portion, and a protruding portion, which is extended in a direction from the base portion, when viewed in a plan view.

In an embodiment, the supporting portion may further include a ground portion, which is bent from the protruding portion and is extended in a direction toward the base portion.

In an embodiment, the supporting portion may further include a connecting portion connecting the base portion to the protruding portion. The connecting portion may have a stepwise structure in a direction away from the cover window.

In an embodiment, the bezel region may include a first region and a second region surrounded by the first region, and the second region may have higher optical transmittance than the first region.

In an embodiment, at least a portion of the protruding portion may overlap with the second region.

In an embodiment, the base portion may overlap with the first region.

In an embodiment, the display device may further include a cover part including a mesh portion, which has a mesh shape and covers the receiver hole, and a coupling portion, which is bent from the mesh portion and is extended toward the separation gap. The mesh portion may be exposed by the opening.

According to one or more embodiments of the inventive concept, a window assembly may include a cover window including a front surface and a rear surface opposite each other, the front surface including a transmission region and a bezel region adjacent to the transmission region, an opening overlapping with the bezel region and being defined in the cover window, a stiffener including a supporting portion, which includes a top portion facing the rear surface and is arranged to have a separation gap between the rear surface and the top portion, and an insertion portion, which is bent from the supporting portion and is inserted into the opening, a receiver hole being defined in the insertion portion, and a cover part between the cover window and the stiffener, at least a portion of the cover part being exposed by the opening. The supporting portion may include a bottom portion opposite the top portion and a side portion connecting the top portion to the bottom portion, and at least a portion of the side portion may be inclined toward the top portion.

In an embodiment, among the supporting portion, the top portion connected to the inclined side portion may have a chamfered shape, in a cross-sectional view.

In an embodiment, the portion of the side portion inclined toward the top portion may include a curved portion.

In an embodiment, the supporting portion may include a base portion, which is connected to the insertion portion, and a protruding portion, which is extended in a direction from the base portion, when viewed in a plan view.

In an embodiment, the protruding portion may include a ground portion, which is bent in a direction toward the bottom portion.

In an embodiment, the supporting portion may further include a connecting portion connecting the base portion to the protruding portion, and the connecting portion may have a stepwise structure in a direction away from the cover window.

In an embodiment, the bezel region may include a first region and a second region having an optical transmittance higher than that of the first region. At least a portion of the protruding portion may overlap with the first region.

According to one or more embodiments of the inventive concept, a display device may include a cover window including a front surface and a rear surface opposite each other, the front surface including a transmission region and a bezel region adjacent to the transmission region, an opening overlapping with the bezel region being defined in the cover window, a stiffener including a supporting portion, which includes a top portion facing the rear surface and is arranged to have a separation gap between the rear surface and the top portion, and an insertion portion, which is bent from the supporting portion and is inserted into the opening, a receiver hole being defined in the insertion portion, a cover part between the cover window and the stiffener, at least a portion of the cover part being exposed by the opening, and a display panel including a pixel to provide an image to the transmission region. At least a portion of a corner of the supporting portion adjacent to the top portion may have a chamfered shape.

In an embodiment, the supporting portion may include a bottom portion opposite the top portion and a side portion connecting the top portion to the bottom portion, and at least a portion of the side portion may be inclined toward the top portion.

In an embodiment, the bezel region may include a first region and a second region having an optical transmittance higher than that of the first region. At least a portion of the supporting portion may overlap with the first region.

### BRIEF DESCRIPTION OF THE DRAWINGS

Example embodiments will be more clearly understood from the following brief description taken in conjunction with the accompanying drawings. The accompanying drawings represent some non-limiting, example embodiments as described herein.

FIG. 1 is a perspective view illustrating an assembled structure of a display device according to an embodiment of the inventive concept.

FIG. 2 is a perspective view illustrating an exploded structure of a display device according to an embodiment of the inventive concept.

FIG. 3A is a plan view illustrating a display panel according to an embodiment of the inventive concept.

FIG. 3B is an equivalent circuit diagram illustrating a pixel according to an embodiment of the inventive concept.

FIG. 4A is a partial plan view illustrating a window assembly according to an embodiment of the inventive concept.

FIG. 4B is a cross-sectional view taken along the line I-I′ of FIG. 4A.

FIG. 4C is a perspective view illustrating a receiver unit according to an embodiment of the inventive concept.

FIG. 4D is a cross-sectional view taken along the line II-II′ of FIG. 4C.

FIG. 5 is a cross-sectional view illustrating a receiver unit according to an embodiment of the inventive concept.

FIG. 6 is a perspective view illustrating a receiver unit according to an embodiment of the inventive concept.

FIG. 7A is a perspective view illustrating a receiver unit according to an embodiment of the inventive concept.

FIG. 7B is a cross-sectional view illustrating a receiver unit according to an embodiment of the inventive concept.

FIG. 7C is a partial plan view illustrating a window assembly according to an embodiment of the inventive concept.

FIG. 8A is a perspective view illustrating a receiver unit according to an embodiment of the inventive concept.

FIG. 8B is a cross-sectional view taken along the line III-III′ of FIG. 8A.

FIG. 9A is a perspective view illustrating a receiver unit according to an embodiment of the inventive concept.

FIG. 9B is a cross-sectional view taken along the line IV-IV′ of FIG. 9A.

It is to be understood that these figures are intended to illustrate general characteristics of methods, structures, and/or materials utilized in certain example embodiments and to supplement the written description provided below. These drawings may not, however, be to scale and may not precisely reflect the precise structural or performance characteristics of any given embodiment, and should not be interpreted as defining or limiting the range of values or properties encompassed by example embodiments. For example, the relative thicknesses and positioning of components, layers, regions, and/or structural elements may be reduced or exaggerated for clarity. The use of similar or same reference numerals in the various drawings is intended to indicate the presence of a similar or same element or feature.

### DETAILED DESCRIPTION

Some example embodiments of the inventive concepts will now be described more fully with reference to the accompanying drawings, in which some example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions may be exaggerated for clarity. Like reference numerals in the drawings denote like elements, and, thus, their repeated description may be omitted.

It is to be understood that when an element is referred to as being “connected” or “coupled” to another element, it may be directly connected or coupled to the other element or one or more intervening elements may be present. In contrast, when an element is referred to as being “directly connected” or “directly coupled” to another element, there are no intervening elements present. As used herein, the term “and/or” includes any and all combinations of one or more of the associated listed items. Other terms used to describe the relationship between elements or layers should be interpreted in a like fashion (e.g., “between” versus “directly between,” “adjacent” versus “directly adjacent,” or “on” versus “directly on”).

It is to be understood that, although the terms “first,” “second,” etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures. For example, if the device in the figures is turned over, elements described as “below” or “beneath” other elements or features would then be oriented above the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

The terminology used herein is for the purpose of describing particular embodiments and is not intended to be limiting of example embodiments. As used herein, the singular forms “a,” “an,” and “the” are intended to include the plural forms as well, unless the context clearly indicates otherwise. It is to be further understood that the terms “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments of the inventive concepts are described herein with reference to cross-sectional illustrations that may be schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments of the inventive concepts belong. It is to be further understood that terms, such as those defined in commonly-used dictionaries, should be interpreted as having a meaning that is consistent with their meaning in the context of the relevant art and are not to be interpreted in an idealized or overly formal sense unless expressly so defined herein.

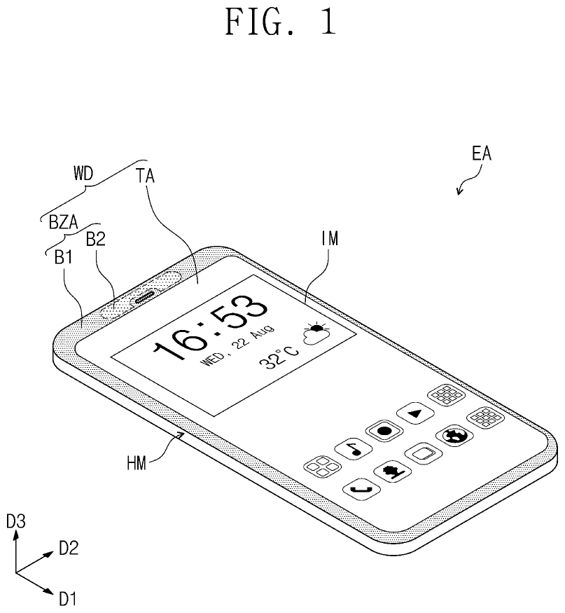

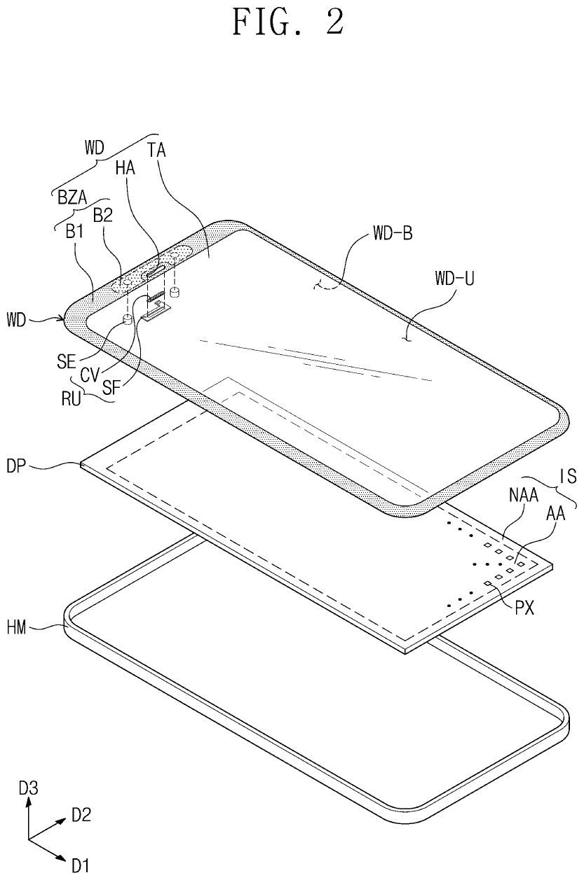

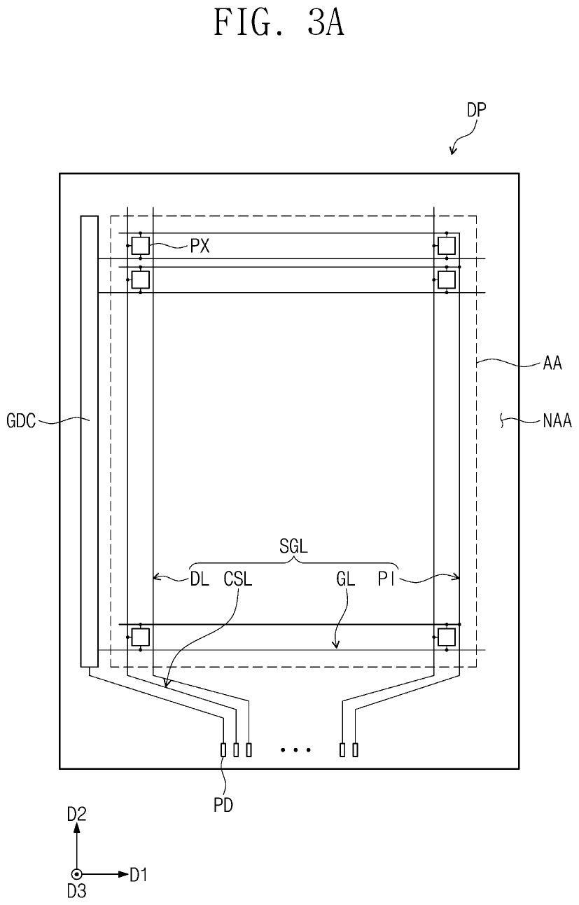

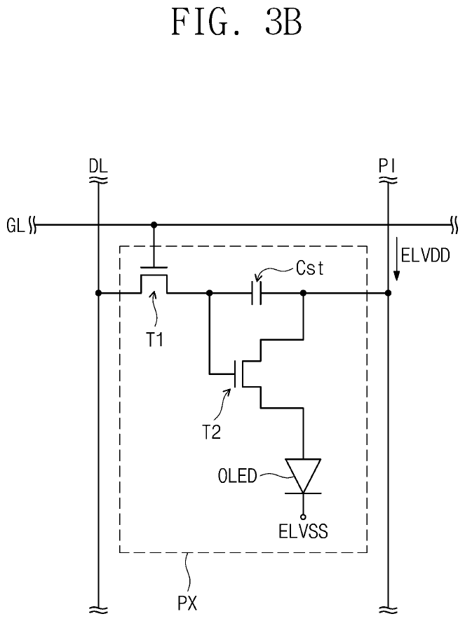

FIG. 1 is a perspective view illustrating an assembled structure of a display device according to an embodiment of the inventive concept; FIG. 2 is a perspective view illustrating an exploded structure of a display device according to an embodiment of the inventive concept; FIG. 3A is a plan view illustrating a display panel according to an embodiment of the inventive concept; and FIG. 3B is an equivalent circuit diagram illustrating a pixel according to an embodiment of the inventive concept.

Referring to FIGS. 1 and 2, a display device EA may display an image IM in a third direction D3 that is normal to a plane defined by a first direction D1 and a second direction D2. In an embodiment, the display device EA may include a cover window WD, a receiver unit RU, sensing units SE, a display panel DP, and a housing member HM.

The cover window WD may include a front surface WD-U, which is exposed to the outside, and a rear surface WD-B, which is opposite to the front surface WD-U. The image IM displayed on the display panel DP may be seen by a user through the front surface WD-U. The cover window WD may include a transmission region TA and a bezel region BZA, when viewed in a plan view.

The transmission region TA may allow an incident light to pass therethrough. The transmission region TA may have a shape corresponding to an active region AA of the display panel DP. For example, the transmission region TA may overlap entirely or partially with a front surface of the active region AA. The image IM, which is displayed on the active region AA of the display panel DP, may be provided to a user through the transmission region TA.

The bezel region BZA may have relatively low optical transmittance, compared with the transmission region TA. The bezel region BZA may define a shape of the transmission region TA. The bezel region BZA may be adjacent to the transmission region TA and may enclose or surround the transmission region TA. The bezel region BZA may have a color (e.g., a predetermined color). The bezel region BZA may cover a peripheral region NAA of the display panel DP and may prevent or substantially prevent the peripheral region NAA from being recognized by a user.

The cover window WD may be optically transparent. For example, the cover window WD may be formed of or include glass or plastic. The cover window WD may have a single- or multi-layered structure. For example, the cover window WD may have a stacked structure including a plurality of plastic films, which are coupled to each other by an adhesive layer, or may have a stacked structure including a glass substrate and a plastic film, which are coupled to each other by an adhesive layer.

In an embodiment, the bezel region BZA may include a first region B1 and a second region B2. The first region B1 may enclose or surround the second region B2. In an embodiment, the first region B1 may be printed or deposited with a light-blocking material. The second region B2 may have higher optical transmittance than the first region B1. For example, the second region B2 may be printed or deposited with a material having an optical transmittance that is higher than that of the material printed or deposited on the first region B1.

For convenience in description and illustration, the first region B1 and the second region B2 having different optical transmittance are illustrated with different shadow patterns in FIGS. 1 and 2, but the first region B1 and the second region B2 as seen by a user may have substantially the same color. In a case in which the first and second regions B1 and B2 are of the same color, it may be possible to prevent or substantially prevent a border between the first and second regions B1 and B2 from being recognized by a user.

The second region B2 may be a region overlapped with the sensing units SE. Thus, the sensing units SE may receive light or a user's biometric information passing through the second region B2. In addition, the second region B2 may be configured to have optical transmittance higher than the first region B1, and in this case, it may be possible to effectively secure an amount of light to be incident to the sensing units SE overlapped with the second region B2.

FIGS. 1 and 2 illustrate an example in which the second region B2 is provided near an opening HA, but the inventive concept is not limited to this example. For example, the shape and size of the second region B2 may be variously changed such that the second region B2 is overlapping with the sensing units SE.

In an embodiment, the opening HA may be defined in the cover window WD. The opening HA may be a space, which is defined to penetrate the cover window WD in the third direction D3. The opening HA may be a space, in which the receiver unit RU and/or a speaker SP to be described below may be inserted. The opening HA may be overlapped with the first region B1. In an embodiment, the opening HA may be formed to be spaced apart from the second region B2.

In an embodiment, the receiver unit RU may include a stiffener SF and a cover part CV. The receiver unit RU may be disposed on or near the rear surface WD-B of the cover window WD. The receiver unit RU may be disposed to be overlapped with the bezel region BZA of the rear surface WD-B of the cover window WD and to be spaced apart from the transmission region TA. The stiffener SF and the cover part CV will be described in more detail below.

The sensing units SE may be disposed on the rear surface WD-B of the cover window WD. In an embodiment, the sensing units SE may be overlapped with the second region B2 but may not be overlapped with the transmission region TA.

In an embodiment, the sensing units SE may include a light source part or an iris camera. For example, the light source part may be an infrared light emitting diode (IR LED), and the iris camera may obtain an image of a user's eye or information of a user's iris using near infrared light emitted from the IR LED.

In an embodiment, the sensing units SE may include at least one of a light source indication lamp, an illumination sensor, or a proximity sensor. The sensing units SE may receive information of a user's iris, a distance to a user, or a light amount in an external environment, through the second region B2.

FIG. 2 illustrates an example in which a pair of the sensing units SE are spaced apart from each other in the second direction D2 with the receiver unit RU interposed therebetween, but the inventive concept is not limited to this example. For example, the position of the sensing units SE may be variously changed such that it is overlapped with the second region B2.

Referring to FIG. 3A, the display panel DP according to an embodiment of the inventive concept may include the active region AA and the peripheral region NAA. In an embodiment, the peripheral region NAA may have a closed-line shape enclosing the active region AA.

The display panel DP may include a driving circuit GDC, a plurality of signal lines SGL, a plurality of pixels PX, and a plurality of pads PD. The pixels PX may be disposed in the active region AA. In an embodiment, each of the pixels PX may include an organic light emitting element and a driving circuit connected thereto.

The driving circuit GDC may include a scan driving circuit. The scan driving circuit may generate a plurality of scan signals and sequentially output the scan signals to a plurality of scan lines GL to be described below. The scan driving circuit may further output other control signals to the driving circuit of the pixels PX. In an embodiment, the driving circuit GDC may be formed during a process for forming the driving circuit of the pixels PX.

The signal lines SGL may include scan lines GL, data lines DL, a power line PI, and a control signal line CSL. Each of the scan lines GL may be connected to corresponding ones of the pixels PX, and each of the data lines DL may be connected to corresponding ones of the pixels PX. The power line PI may be connected to the pixels PX. The control signal line CSL may provide control signals to the scan driving circuit.

The signal lines SGL may be connected to a circuit substrate (not shown). For example, the signal lines SGL may be connected to a timing control circuit, which may be provided in the form of an integrated circuit (IC) chip mounted on the circuit board. However, the inventive concept is not limited to this example, and, in an embodiment, the IC chip may be disposed on the peripheral region NAA and may be connected to the signal lines SGL.

In an embodiment, the pads PD may be connected to respective ones of the signal lines SGL and may be connected to a flexible circuit substrate, on which driving chips (not shown) are mounted. Each of the signal lines SGL may transmit or receive data, which are provided from the flexible circuit substrate, through corresponding ones of the pads PD.

FIG. 3B illustrates one scan line GL, one data line DL, one power line PI, and one pixel PX connected thereto. However, the structure of the pixel PX is not limited to the example of FIG. 3B and may be variously changed.

The pixel PX may include a first or switching transistor T1, a second or driving transistor T2, and a capacitor Cst, which are used as parts of a pixel driving circuit for driving an organic light emitting element OLED. The second transistor T2 may receive a first power voltage ELVDD through the power line PI, and the organic light emitting element OLED may be applied with a second power voltage ELVSS. The second power voltage ELVSS may be lower than the first power voltage ELVDD.

If a scan signal is applied to a scan line GL, the first transistor T1 may output a data signal applied to the data line DL in response to the scan signal. The capacitor Cst may be charged to have a voltage corresponding to a data signal received from the first transistor T1. The second transistor T2 may be connected to the organic light emitting element OLED. The second transistor T2 may control a driving current flowing through the organic light emitting element OLED, based on an amount of electric charges stored in the capacitor Cst.

The equivalent circuit in FIG. 3B is an example embodiment of possible equivalent circuits of the pixel PX, but the inventive concept is not limited thereto. In an embodiment, the pixel PX may further include a plurality of transistors and at least one capacitor. The organic light emitting element OLED may be disposed between and coupled to the power line PI and the second transistor T2.

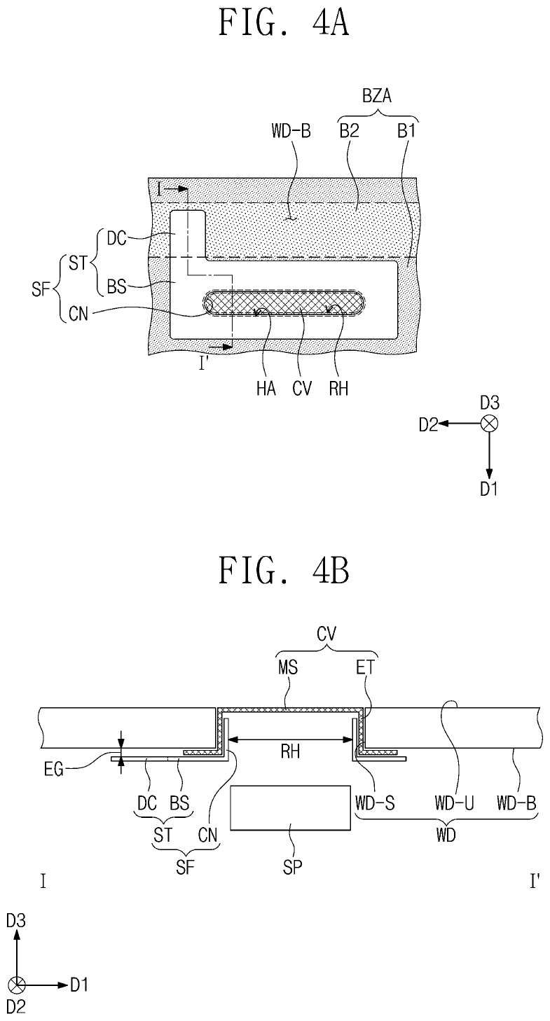

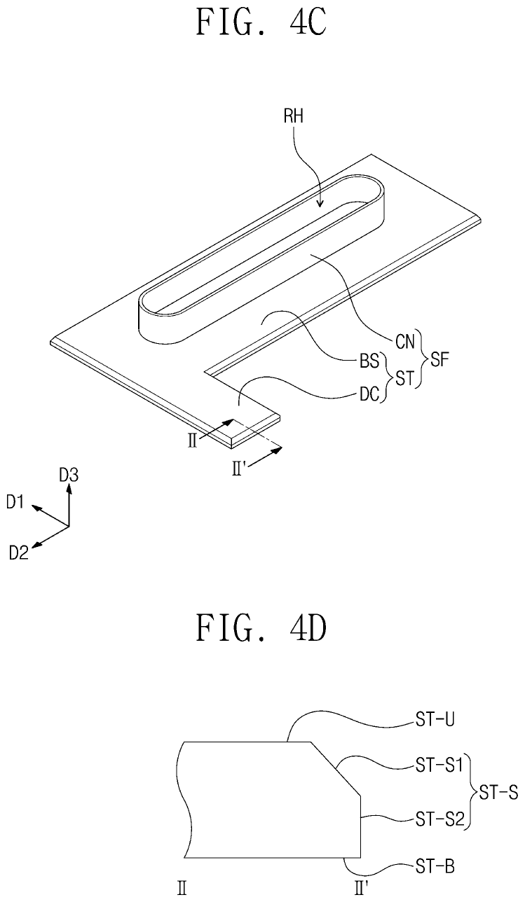

Although not shown, the display device EA according to an embodiment of the inventive concept may further include an electronic module. The electronic module may include any of various functional modules, which are used to operate the display device EA. The electronic module may be electrically connected to the display panel DP through a connector or the like. For example, the electronic module may include a camera, a light- or heat-sensing device, or the speaker SP of FIG. 4B.

The housing member HM may be disposed below the display panel DP. The housing member HM may be coupled to the cover window WD to define an outer appearance of the display device EA. The housing member HM may include a material having relatively high strength or stiffness. For example, the housing member HM may include any of a plurality of frames and/or plates, each of which is formed of at least one of glass, plastic, or metallic materials.

The housing member HM may provide a storage space. The display panel DP and an electronic module may be disposed in the storage space and may be protected from an external impact.

FIG. 4A is a partial plan view illustrating a window assembly according to an embodiment of the inventive concept; FIG. 4B is a cross-sectional view taken along the line I-I′ of FIG. 4A; FIG. 4C is a perspective view illustrating a receiver unit according to an embodiment of the inventive concept; and FIG. 4D is a cross-sectional view taken along the line II-II′ of FIG. 4C. The receiver unit RU coupled with the cover window WD is illustrated in FIGS. 4A and 4B.

Referring to FIGS. 4A and 4B, the receiver unit RU may include the stiffener SF and the cover part CV. The stiffener SF may include a supporting portion ST and an insertion portion CN. In an embodiment, the supporting portion ST and the insertion portion CN may be a single connected element, but for convenience in description, are illustrated as separate elements. The cover window WD may include the front surface WD-U exposed to the outside, the rear surface WD-B opposite to the front surface, and a side surface WD-S connecting the front surface WD-U to the rear surface WD-B. The opening HA may be a space, which is substantially enclosed by the side surface WD-S of the cover window WD.

In an embodiment, the supporting portion ST may include a base portion BS and a protruding portion DC. The protruding portion DC may be extended in a direction (e.g., a specific direction) from the base portion BS. For example, the protruding portion DC may be extended in the first direction D1 to be overlapped with the second region B2.

The supporting portion ST may be overlapped with the first region B1 and the second region B2. For example, the base portion BS of the supporting portion ST may be overlapped with the first region B1, and the protruding portion DC of the supporting portion ST may be overlapped with the second region B2.

The supporting portion ST may be spaced apart from the rear surface WD-B of the cover window WD to define a separation gap EG therebetween. The separation gap EG may be a region, which is formed by the cover part CV and is disposed between the cover window WD and the stiffener SF. Accordingly, the protruding portion DC may be vertically spaced apart from the second region B2 and may be overlapped with the second region B2, when viewed in a plan view.

The insertion portion CN may be bent in the third direction D3 from the supporting portion ST and may be inserted in the opening HA defined in the cover window WD. The insertion portion CN may be disposed to be spaced apart from the side surface WD-S of the cover window WD, with the cover part CV interposed therebetween. The insertion portion CN may be overlapped with the side surface WD-S of the cover window WD defining the opening HA.

The insertion portion CN may define a receiver hole RH. The receiver hole RH may be a space enclosed or surrounded by the insertion portion CN. In an embodiment, the receiver hole RH may be overlapped with the speaker SP, which is one of electronic modules included in the display device EA.

In an embodiment, the cover part CV may include a mesh portion MS and a coupling portion ET. The cover part CV may be disposed in the separation gap EG, which is disposed between the cover window WD and the stiffener SF. The mesh portion MS may cover the receiver hole RH. The mesh portion MS may have a mesh shape. A sound wave, which is provided from the speaker SP, may be effectively transferred to the outside through the mesh portion MS.

The coupling portion ET may be bent in the third direction D3 from the mesh portion MS and may be extended toward the separation gap EG. For example, the coupling portion ET may be extended from the mesh portion MS to be overlapped with the side surface WD-S of the cover window WD and the insertion portion CN and may be extended from the mesh portion MS to be overlapped with the rear surface WD-B of the cover window and the supporting portion ST. The coupling portion ET may be welded or coupled to at least one of the supporting portion ST and the insertion portion CN.

Referring to FIGS. 4C and 4D, the supporting portion ST of the stiffener SF may include a top portion ST-U, a bottom portion ST-B, and a side portion ST-S connecting the top portion ST-U to the bottom portion ST-B. The top portion ST-U may face the rear surface WD-B of the cover window WD. For example, the top portion ST-U of the supporting portion ST may face the rear surface WD-B of the cover window WD with the separation gap EG interposed therebetween.

In an embodiment, the side portion ST-S may include a first portion ST-S1 and a second portion ST-S2. The first portion ST-S1 may connect the top portion ST-U to the second portion ST-S2, and the second portion ST-S2 may connect the bottom portion ST-B to the first portion ST-S1. At least a portion of the side portion ST-S may be inclined toward the top portion ST-U.

In an embodiment, a corner of the stiffener SF has a chamfered shape. In an embodiment, a corner of the supporting portion ST adjacent to the top portion ST-U may have the chamfered shape. For example, the first portion ST-S1 connected to the top portion ST-U may be inclined toward the top portion ST-U.

However, the inventive concept is not limited to this example, and, in an embodiment, the second portion ST-S2 may be omitted. In this case, the side portion ST-S may have a shape inclined from the top portion ST-U to the bottom portion ST-B, but the inventive concept is not limited to this example or a specific embodiment.

In an embodiment, the corner of the supporting portion ST, which is adjacent to the top portion ST-U and has the chamfered shape, may be formed to have a closed-line shape enclosing the entire corner of the top portion ST-U.

In an embodiment, a corner of the top portion ST-U of the stiffener SF adjacent to the rear surface WD-B of the cover window WD may have a chamfered shape and, thus, it may be possible to prevent or suppress the bezel region BZA of the cover window WD from being damaged by an impact exerted on the supporting portion ST.

That is, by increasing an area of a corner portion of the supporting portion ST in direct contact with the bezel region BZA, it may be possible to prevent or substantially prevent layers, which are printed or coated on the rear surface WD-B of the cover window WD, from being damaged by impact.

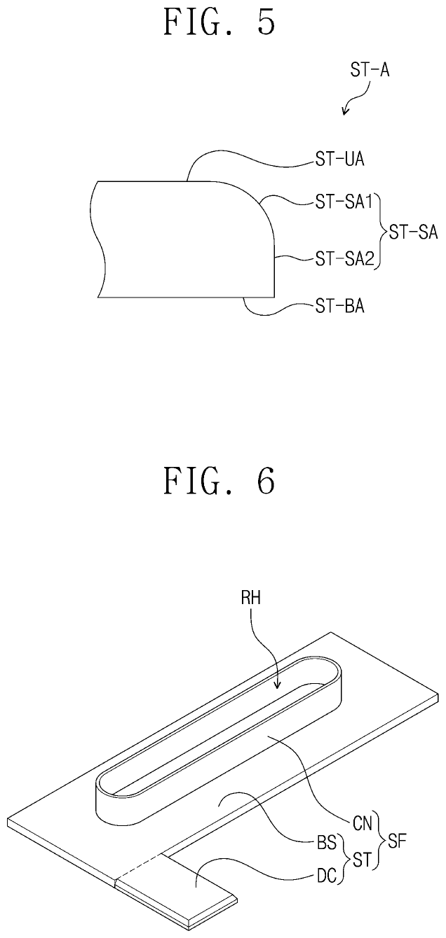

FIG. 5 is a cross-sectional view illustrating a receiver unit according to an embodiment of the inventive concept. For concise description, an element previously described with reference to FIGS. 4A to 4D may be identified by the same reference numeral without repeating an overlapping description thereof.

In an embodiment, a supporting portion ST-A may include a top portion ST-UA, a bottom portion ST-BA, and a side portion ST-SA connecting the top portion ST-UA to the bottom portion ST-BA.

In an embodiment, the side portion ST-SA may include a first portion ST-SA1 and a second portion ST-SA2. The first portion ST-SA1 may connect the top portion ST-UA to the second portion ST-SA2, and the second portion ST-SA2 may connect the bottom portion ST-BA to the first portion ST-SA1. At least a portion of the side portion ST-SA may be inclined toward the top portion ST-UA. In an embodiment, the portion of the side portion ST-SA inclined toward the top portion ST-UA may include a curved portion. For example, the first portion ST-SA1 connected to the top portion ST-UA may include a curved portion.

However, the inventive concept is not limited to this example, and, in an embodiment, the second portion ST-SA2 may be omitted. In this case, the side portion ST-SA may be a curved portion connecting the top portion ST-UA to the bottom portion ST-BA, but the inventive concept is not limited to this example.

FIG. 6 is a perspective view illustrating a receiver unit according to an embodiment of the inventive concept. For concise description, an element previously described with reference to FIGS. 4A to 4D may be identified by the same reference numeral without repeating an overlapping description thereof.

Referring to FIG. 6, in an embodiment, a chamfered shape of a corner of the supporting portion ST adjacent to the top portion ST-U may be locally formed in only the protruding portion DC, unlike in FIG. 4C. As shown in FIG. 4B, an element, which is in contact with the rear surface WD-B of the cover window WD by an impact, is a portion of the protruding portion DC, and, thus, the chamfered shape may be formed in a region of the top portion ST-U of the supporting portion ST, which is defined as the protruding portion DC. However, the inventive concept is not limited to this example, and the chamfered shape may be formed in an end of the protruding portion DC, which is in contact with the rear surface WD-B of the cover window WD (e.g., see FIG. 4B).

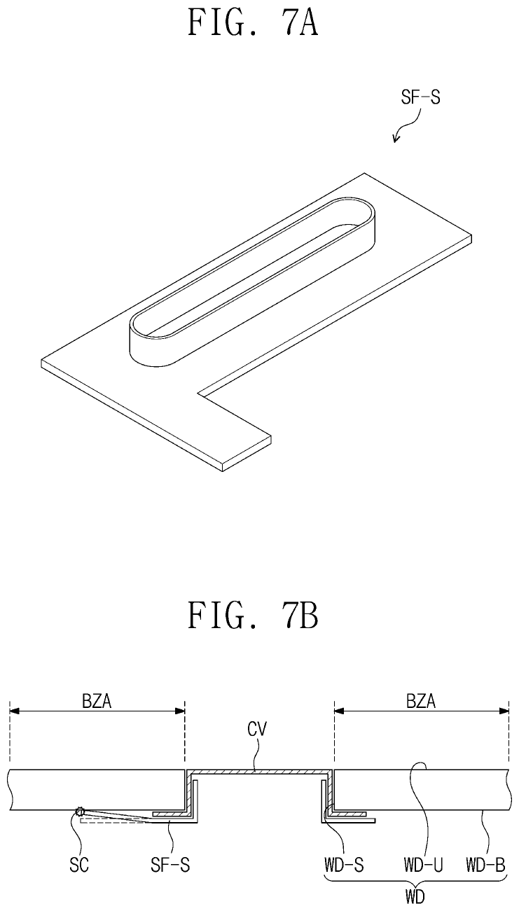

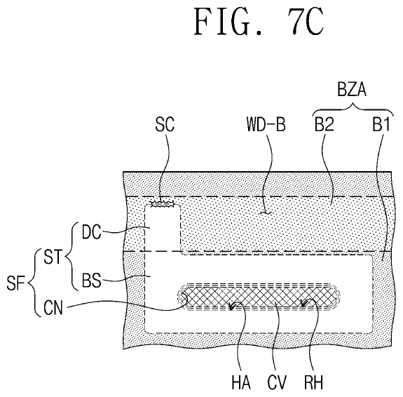

FIG. 7A is a perspective view illustrating a receiver unit according to an embodiment of the inventive concept; FIG. 7B is a cross-sectional view illustrating a receiver unit according to an embodiment of the inventive concept; and FIG. 7C is a partial plan view illustrating a window assembly according to an embodiment of the inventive concept.

Referring to FIGS. 7A to 7C, a stiffener SF-S according to an embodiment of the inventive concept may not have the chamfered shape in a corner thereof.

In this case, the cover window WD may be coupled to the stiffener SF-S. However, in the case in which there is an impact in steps of using, transferring, and storing a display device, a portion of the stiffener SF-S may be in contact with the rear surface WD-B of the cover window WD.

In the case in which the portion of the stiffener SF-S is in contact with the cover window WD, damage SC may occur in the rear surface WD-B of the cover window WD. For example, a portion of the bezel region BZA, which is printed or deposited on the rear surface WD-B of the cover window WD, may be removed or damaged, and the damaged portion SC may be recognized by a user. To illustrate the damaged portion SC in the rear surface WD-B of the cover window WD, the stiffener SF-S is depicted by a dotted line in FIG. 7B.

The display device according to an embodiment of the inventive concept may include the stiffener SF (e.g., see FIG. 4C), which is in contact with the bezel region BZA of the cover window WD. Here, a corner of the stiffener SF may have a chamfered shape and, thus, make it possible to prevent or suppress the bezel region BZA from being damaged when the cover window WD is in contact with the stiffener SF. Thus, the display device EA (e.g., see FIG. 1) may have improved reliability.

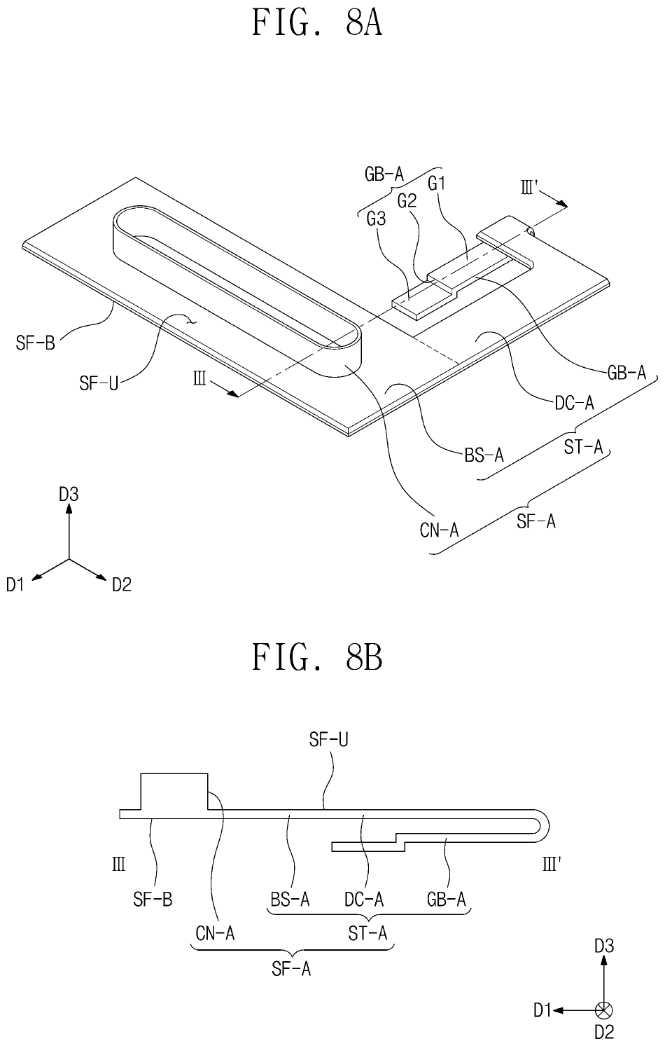

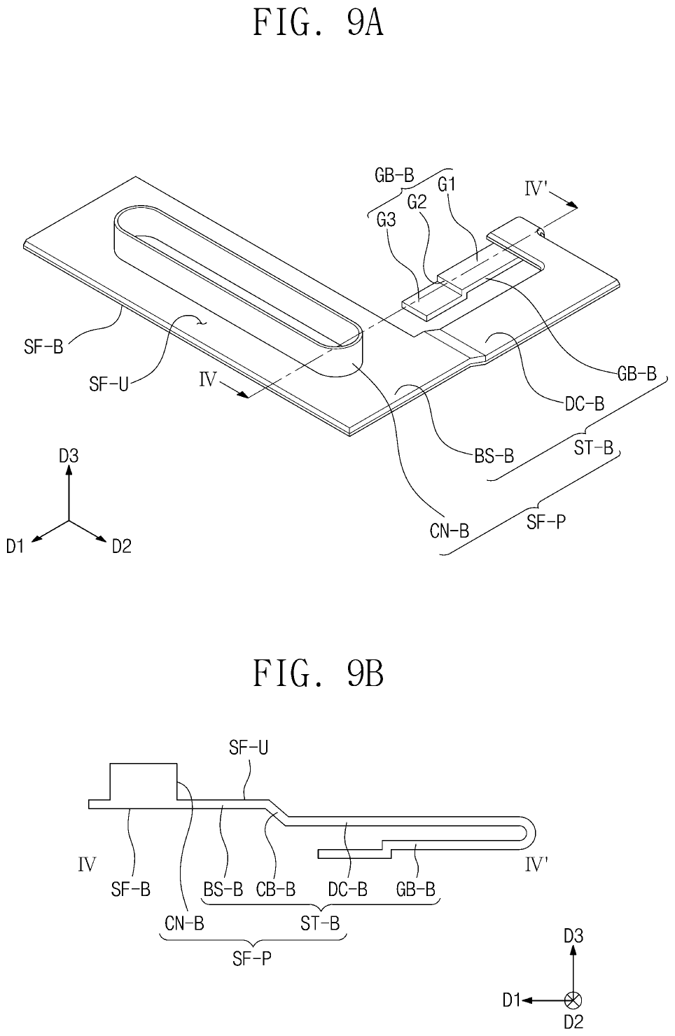

FIG. 8A is a perspective view illustrating a receiver unit according to an embodiment of the inventive concept; FIG. 8B is a cross-sectional view taken along the line III-III′ of FIG. 8A; FIG. 9A is a perspective view illustrating a receiver unit according to an embodiment of the inventive concept; and FIG. 9B is a cross-sectional view taken along the line IV-IV′ of FIG. 9A. For concise description, an element previously described with reference to FIGS. 4A to 4D may be identified by the same reference numeral without repeating an overlapping description thereof.

Referring to FIGS. 8A and 8B, a stiffener SF-A according to an embodiment of the inventive concept may include a supporting portion ST-A and a connecting portion CN-A. The supporting portion ST-A may include a base portion BS-A, a protruding portion DC-A, and a ground portion GB-A. The base portion BS-A and the protruding portion DC-A may be connected to each other to define a single flat plane. The base portion BS-A and the protruding portion DC-A may correspond to the base portion BS and the protruding portion DC of FIG. 4C.

In an embodiment, the ground portion GB-A may include a first portion G1, a second portion G2, and a third portion G3. The ground portion GB-A may be bent from the protruding portion DC-A and may be extended in a direction toward the base portion BS-A. In addition, the ground portion GB-A may be bent in a direction away from the cover window WD (e.g., see FIG. 4B).

For example, the first portion G1 may be bent from the protruding portion DC-A. The first portion G1 may be vertically spaced apart from a bottom portion SF-B of the stiffener SF-A, the bottom portion SF-B being opposite to a top portion SF-U. The second portion G2 may be disposed to form a stepwise structure with the first portion G1 and may be connected to the third portion G3.

Referring to FIGS. 9A and 9B, a stiffener SF-P according to an embodiment of the inventive concept may include a supporting portion ST-B and a connecting portion CN-B. The supporting portion ST-B may include a base portion BS-B, a connecting portion CB-B, a protruding portion DC-B, and a ground portion GB-B.

The base portion BS-B and the protruding portion DC-B may correspond to the base portion BS and the protruding portion DC of FIG. 4C. In addition, the first to third portions G1, G2, and G3 of the ground portion GB-B may correspond to the first to third portions G1, G2, and G3 of the ground portion GB-A described with reference to FIGS. 8A and 8B.

In an embodiment, the stiffener SF-P may further include the connecting portion CB-B. The connecting portion CB-B may connect the base portion BS-B to the protruding portion DC-B. The connecting portion CB-B may form a stepwise structure in a direction away from the cover window WD (e.g., see FIG. 4C). Unlike the base portion BS-A and the protruding portion DC-A defining the single flat plane shown in FIG. 8A, the base portion BS-B and the protruding portion DC-B according to an embodiment of the inventive concept may form a stepwise structure with the connecting portion CB-B interposed therebetween and may define planes different from each other.

A surface of the ground portion GB-A or GB-B may be connected to an element, which may be one of unillustrated elements of the display device EA (e.g., see FIG. 1) and may be used to discharge electrostatic charges to the outside. For example, the third portion G3 of the ground portion GB-A or GB-B may be connected to an element of the display device EA to discharge electrostatic charges, which may be supplied from the cover part CV (e.g., see FIG. 4B), to the outside. This may make it possible to improve reliability of the display device EA.

In a display device according to one or more embodiments of the inventive concept, a receiver unit in contact with a bezel region of a cover window may have corners, at least one of which has a chamfered shape, and thus may reduce or minimize damage of the bezel region which may occur when the cover window is in contact with the receiver unit. Accordingly, a display device with improved reliability may be provided.

While some embodiments of the inventive concepts have been particularly shown and described, it will be understood by one of ordinary skill in the art that variations in form and detail may be made therein without departing from the spirit and scope of the attached claims.

What is claimed is:

1. A display device, comprising:
a cover window comprising a front surface and a rear surface opposite each other, the front surface comprising a transmission region and a bezel region adjacent to the transmission region, an opening overlapping with the bezel region being defined in the cover window;
a stiffener comprising a supporting portion, which comprises a top portion facing the rear surface and is arranged to have a separation gap between the rear surface and the top portion, and an insertion portion, which is bent from the supporting portion and is inserted into the opening, a receiver hole being defined in the insertion portion; and
a display panel comprising a pixel to provide an image to the transmission region,
wherein at least a portion of a corner of the supporting portion adjacent to the top portion has a chamfered shape.

2. The display device of claim 1, wherein the supporting portion comprises a bottom portion opposite the top portion and a side portion connecting the top portion to the bottom portion, and
at least a portion of the side portion is inclined toward the top portion.

3. The display device of claim 2, wherein the portion of the side portion inclined toward the top portion comprises a curved portion.

4. The display device of claim 1, wherein the supporting portion comprises a base portion, which is connected to the insertion portion, and a protruding portion, which is extended in a direction from the base portion, when viewed in a plan view.

5. The display device of claim 4, wherein the supporting portion further comprises a ground portion, which is bent from the protruding portion and is extended in a direction toward the base portion.

6. The display device of claim 4, wherein the supporting portion further comprises a connecting portion connecting the base portion to the protruding portion, and
the connecting portion has a stepwise structure in a direction away from the cover window.

7. The display device of claim 4, wherein the bezel region comprises a first region and a second region surrounded by the first region, and
the second region has a higher optical transmittance than the first region.

8. The display device of claim 7, wherein at least a portion of the protruding portion overlaps with the second region.

9. The display device of claim 7, wherein the base portion overlaps with the first region.

10. The display device of claim 1, further comprising a cover part comprising a mesh portion, which has a mesh shape and covers the receiver hole, and a coupling portion, which is bent from the mesh portion and is extended toward the separation gap,
wherein the mesh portion is exposed by the opening.

11. A window assembly, comprising:
a cover window comprising a front surface and a rear surface opposite each other, the front surface comprising a transmission region and a bezel region adjacent to the transmission region, an opening overlapping with the bezel region being defined in the cover window;
a stiffener comprising a supporting portion, which comprises a top portion facing the rear surface and is arranged to have a separation gap between the rear surface and the top portion, and an insertion portion, which is bent from the supporting portion and is inserted into the opening, a receiver hole being defined in the insertion portion; and
a cover part between the cover window and the stiffener, at least a portion of the cover part being exposed by the opening,
wherein the supporting portion comprises a bottom portion opposite the top portion and a side portion connecting the top portion to the bottom portion, and
at least a portion of the side portion is inclined toward the top portion.

12. The window assembly of claim 11, wherein, among the supporting portion, the top portion connected to the inclined side portion has a chamfered shape, in a cross-sectional view.

13. The window assembly of claim 11, wherein the portion of the side portion inclined toward the top portion comprises a curved portion.

14. The window assembly of claim 11, wherein the supporting portion comprises a base portion, which is connected to the insertion portion, and a protruding portion, which is extended in a direction from the base portion, when viewed in a plan view.

15. The window assembly of claim 14, wherein the protruding portion comprises a ground portion, which is bent in a direction toward the bottom portion.

16. The window assembly of claim 14, wherein the supporting portion further comprises a connecting portion connecting the base portion to the protruding portion, and
the connecting portion has a stepwise structure in a direction away from the cover window.

17. The window assembly of claim 14, wherein the bezel region comprises a first region and a second region having an optical transmittance higher than that of the first region, and
at least a portion of the protruding portion overlaps with the first region.

18. A display device, comprising:
a cover window comprising a front surface and a rear surface opposite each other, the front surface comprising a transmission region and a bezel region adjacent to the transmission region, an opening overlapping with the bezel region being defined in the cover window;
a stiffener comprising a supporting portion, which comprises a top portion facing the rear surface and is arranged to have a separation gap between the rear surface and the top portion, and an insertion portion, which is bent from the supporting portion and is inserted into the opening, a receiver hole being defined in the insertion portion;
a cover part between the cover window and the stiffener, at least a portion of the cover part being exposed by the opening; and
a display panel comprising a pixel to provide an image to the transmission region,
wherein at least a portion of a corner of the supporting portion adjacent to the top portion has a chamfered shape.

19. The display device of claim 18, wherein the supporting portion comprises a bottom portion opposite the top portion and a side portion connecting the top portion to the bottom portion, and
at least a portion of the side portion is inclined toward the top portion.

20. The display device of claim 18, wherein the bezel region comprises a first region and a second region having an optical transmittance higher than that of the first region, and
at least a portion of the supporting portion overlaps with the first region.
